(19) United States
(12) Patent Application Publication
(10) Pub. No.: US 2025/0246516 A1
(43) Pub. Date: Jul. 31, 2025

(54) MULTIZONE THERMAL DEVICE FOR SEMICONDUCTOR STRUCTURES

(71) Applicant: Taiwan Semiconductor Manufacturing Company, Ltd., Hsinchu (TW)

(72) Inventors: Tsunyen Wu, Hsinchu County (TW); Sing Da Jiang, Taichung City (TW); Shih-Wei Liu, Chiayi City (TW); Kathy Wei Yan, Hsinchu (TW); Jun He, Hsinchu County (TW)

(21) Appl. No.: 18/743,957

(22) Filed: Jun. 14, 2024

Related U.S. Application Data
(60) Provisional application No. 63/624,863, filed on Jan. 25, 2024.

(51) Int. Cl. H01L 23/473; H01L 21/66; H01L 23/00; H01L 25/11

(52) U.S. Cl. CPC H01L 23/473; H01L 22/12; H01L 24/13; H01L 24/16; H01L 25/115; H01L 2224/10125; H01L 2224/13023; H01L 2224/16225; H01L 2924/15165

(57) ABSTRACT

A test method and system of testing a semiconductor device is provided. The method includes placing a packaged semiconductor device on a tester and engaging a thermal management component with an upper surface of the packaged semiconductor device. The packaged semiconductor device is tested using the tester, and during the testing a first thermal condition is delivered to a first region of the thermal management component while delivering a second thermal condition is delivered to a second region of the thermal management component. The first thermal condition is different than the second thermal condition.

### CROSS-REFERENCE TO RELATED APPLICATIONS

This application claims priority to U.S. Prov. App. Ser. No. 63/624,863, filed Jan. 25, 2024, the entire disclosure of which is incorporated herein by reference.

### BACKGROUND

Testing is an important step in ensuring an integrated circuit's reliability, integrity, and performance. Thermal management during testing, such as thermal management of the semiconductor structure has become a challenge. This is especially true when addressing packaged semiconductor devices having a plurality of chips or dies within the package such as 2.5D and 3D structures. Although existing thermal management techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a cross-sectional view of a thermal management component interfacing a multi-die packaged device, according to aspects of the present disclosure.

FIG. 2A is a top view of an embodiment of a thermal management component positioned over a device, according to aspects of the present disclosure.

FIGS. 2B, 3A, 3B, 4, 5, 6A, 6B, and 7 illustrate cross-sectional views of embodiments of a thermal management component having various coolant routing configurations, according to aspects of the present disclosure.

FIG. 8 illustrates an embodiment of testing a device while implementing a thermal management control according to aspects of the present disclosure.

FIG. 9 illustrates a block diagram of a device under test (DUT) in a test system having a thermal management component, according to aspects of the present disclosure.

### DETAILED DESCRIPTION

The present disclosure relates generally to semiconductor devices and in particular integrated circuits (IC) included in a multi-die packaged device (also referred to as a multi-chip package or module) including thermal management during testing and operating conditions of said device.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not necessarily mathematically or perfectly vertical and horizontal.

Certain discussions are presented in the present disclosure directed to thermal management during testing of packaged semiconductor structures. One of skill in the art would appreciate that the thermal management components and methods discussed herein are not only solutions or improvements for thermal management of a device under test (DUT), but may also be applied to thermal management of a device in use including, but not limited to, a packaged semiconductor structure implemented in an electronic system such as a computer or other information handling system.

Thermal management during IC testing (or use), such as thermal management of an IC being tested after packaging, has become a challenge. For example, as devices become more sophisticated and as they extend to packaged semiconductor structures including multiple chips or dies, addressing their power and heat generation becomes more challenging. Thermal management of a DUT is beneficial to ensure quality and reliability of the DUT, as well as the testing equipment. Certain cooling mechanisms implemented in testers may provide low cooling efficiency (e.g., air-cooled heat sinks) and/or do not allow for independent control of regions or zones of the DUT such as, for example, independent control of temperature of the surroundings of each die of a multi-die DUT. In further implementations, it may be desired to test die of a multi-die package at different testing temperatures from one another. Thus, lack of independent control of the areas of a multi-die package requires a single temperature test to be performed multiple times.

The present disclosure addresses, in at least some of its embodiments, some or all of these challenges by providing an improved thermal management system for devices such as multi-die packages under testing conditions or otherwise in operation. The thermal management system of the present disclosure, in various embodiments, provides for different zones or regions of a thermal management component that interfaces a multi-chip packaged device to be controlled (through introduction of coolant) independently from one another. Thus, thermal conditions of regions of the multi-chip device can be independently controlled, such as the thermal condition around one die of the multi-die package can be separately controlled from the thermal condition around another die of the multi-die package. By having flexibility in the thermal conditions of regions within a packaged device, testing time can be reduced and binning efficiency can be improved. In some implementations, certain die, such as a high power device, of a multi-die package can experience targeted, improved cooling.

Further benefits of the present disclosure include the opportunity to remove a thermal interface material (TIM) as an interface between a die and a thermal management component. Rather, in some embodiments, direct heat exchange can be provided between a device (e.g., exposed surface of a 3D IC) and a coolant. In some implementations, removal of the TIM provides for more efficiency in transfer of thermal energy from a device. This provides particular benefits in removing heat from a high power device in a multi-die package during operation or testing.

This discussion of benefits is provided for ease of understanding only. Different embodiments may have different advantages, and no particular advantage is required of any embodiment.

The multi-die or chip packages of the present disclosure are exemplary. Various packaging technology provides integration of multiple chips or dies into a single semiconductor device. Depending on the level of stacking, modern semiconductor packages can have what is referred to as a 2.5D structure or a 3D structure. In a 2.5D structure, at least two dies are coupled to a redistribution layer (RDL) structure or an interposer that provides chip-to-chip communication. The at least two dies in a 2.5D structure may not be stacked one over another vertically. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. Various configurations, including 2.5D and 3D structures are encompassed within the multi-chip packaged devices discussed in the present disclosure.

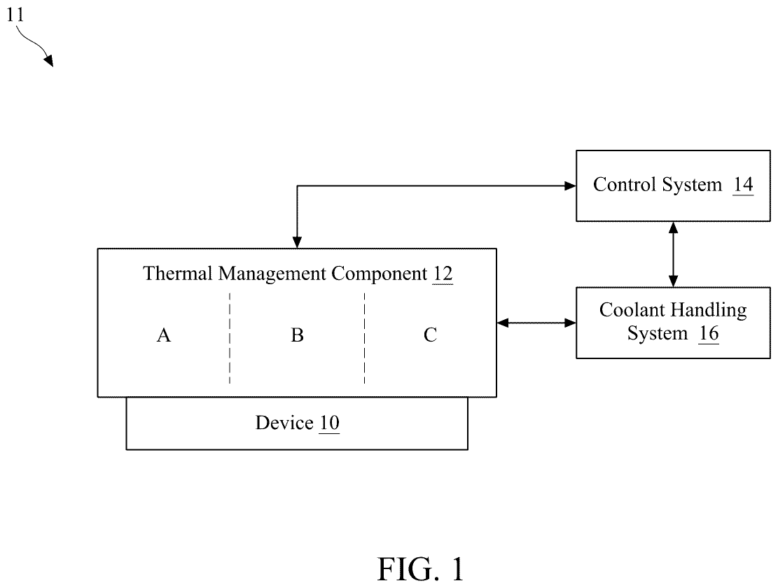

FIG. 1 is a block diagram of thermal management system 11 including a device 10 interfacing a thermal management component 12, which in turn is operably coupled to a control system 14 and a coolant handling system 16. The thermal management system 11 may be included in a tester, a product system such as a computer or information handling system, or the like.

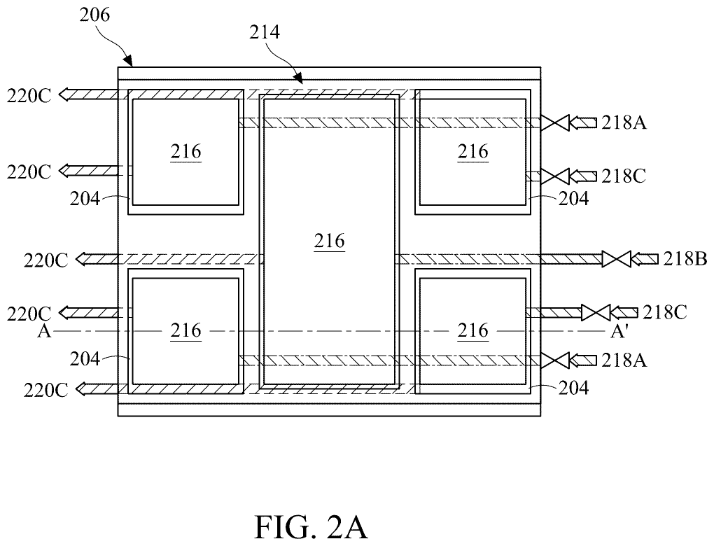

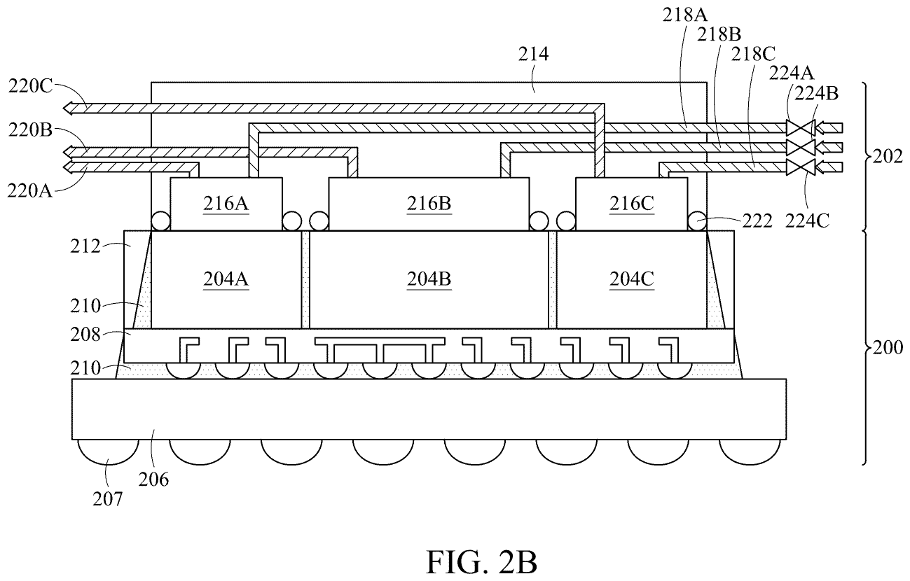

The device 10 may be a packaged semiconductor device including one or more die or chips within the package (i.e., a multi-die or multi-chip package). The device 10 may include at least three chips or die within the package. In some implementations, the device 10 has a 2.5D or 3D structure. Exemplary embodiments of the device 10 are discussed in further detail below including with respect to FIGS. 2A-7.

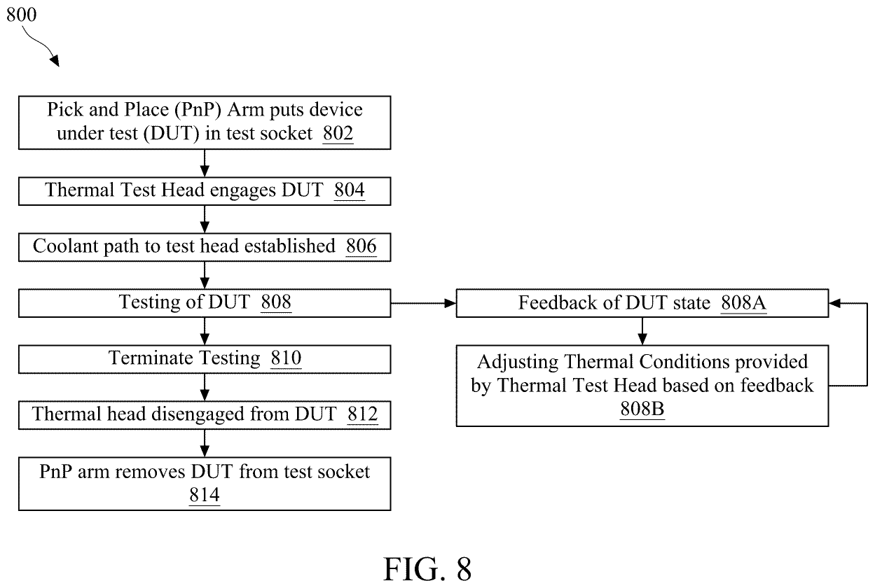

The control system 14 is provided for implementing aspects of the present disclosure. The control system 14 includes a hardware processor and a non-transitory computer readable storage medium encoded with, i.e., storing, a program, i.e., a set of executable instructions. The instructions may be suitable for performing one of more of the functions discussed in the present disclosure including those of the method of FIG. 8. The control system 14 may be operably coupled to the thermal management component 12 and/or the coolant handling system 16. In some implementations, as discussed below, the control system 14 receives data from the thermal management component 12 such as data from thermal sensors disposed on or in the thermal management component 12. And in some implementations, the data received from the thermal management component 12 is used to compute desired output of the coolant handling system 16, and thus, instructions are transferred from the control system 14 to the coolant handling system 16. In an embodiment, instructions are transferred from the control system 14 to the coolant handling system 16 where the instructions are generated based on stored or received data such as design data, device performance data, simulation data, and the like. In an embodiment, instructions are transferred from the control system 14 to the coolant handling system 16 where the instructions are generated based on desired testing conditions (e.g., temperature) for the device 10.

The coolant handling system 16 may provide a series of pumps, valves, pipes, reservoirs, and/or other features suitable for providing a coolant to the thermal management component 12 and receiving coolant after use (i.e., spent coolant) from the thermal management component 12. In some implementations, the coolant is provided by the coolant handling system 16 according to the instructions of the control system 14 for example by operating valves of the coolant handling system. In an embodiment, the coolant of the coolant handling system 16, in particular that provided to the thermal management component 12, is a liquid-phase coolant. In some implementations, the coolant provided from the thermal management component 12 back to the coolant handling system 16 (i.e., spent coolant) is also still in a liquid-phase. However, in some variations, the coolant received from the thermal management component 12 to the coolant handling system16 is in gaseous phase. Various configurations of the coolant handling system 16 are possible including multiple supply lines (e.g., pipes) extending to the thermal management component 12 and multiple return lines (e.g., pipes) extending from the thermal management component 12 to the coolant handling system 16. In an embodiment, the number of supply lines of coolant extending from the coolant handling system 16 to the thermal management component 12 is the same as the number of temperature zones (e.g., A, B., C discussed below) of the thermal management component 12. In other embodiments, the number of supply lines may be less than the number of temperature zones. To be sure, the coolant handling system includes various valves controlling the supply of the coolant to the thermal management component 12, in some cases, the valves controlled by instructions provided by the control system 14.

The thermal management component 12 interfaces the device 10. The thermal management component 12 may directed interface the device 10 such that it physically touches an upper surface of the device 10. In an embodiment, the thermal management component 12 may be a portion of a tester head for performing electrical testing on the device 10. In an embodiment, the thermal management component 12 may be attached to the device 10 as installed in an operating system including the device 10 (e.g., a computer or other information handling system). The thermal management component 12 may include a housing providing a manifold that receives the supply lines and provides the return lines of the coolant handling system 16. The thermal management component 12 may include various compartments or chambers operable to hold the received coolant. As discussed below, the compartments may be sealed compartments directly interfacing an upper surface of the device 10 to provide coolant (e.g., liquid coolant) directly to the device 10 for enhanced heat transfer.

As illustrated, the thermal management component 12 includes a plurality of thermal zones or regions, here illustrated as A, B, and C. Each thermal region may be independently controlled by the control system 14 and have an independent connection (e.g., coolant delivery) from the coolant handling system 16 in some implementations. While three regions are illustrated, any number of regions are possible. In some implementations, the number of regions is at least equal to the number of die or chips in a multi-die package provided as the device 10. In an embodiment, a target thermal condition set point (e.g., temperature) is separately selected for each of regions A, B, and C. And a temperature sensor may be provided for the regions A, B, and C. In an embodiment, a sensor or sensors separately determines a thermal condition (e.g., temperature) of each of regions A, B and C. In an embodiment, the control system 14, through the coolant handling system 16, delivers a different coolant condition (e.g., different temperature, different coolant, different flowrate) to each of the regions A, B and C. Exemplary thermal management components 12 are discussed in further detail below with respect to FIGS. 2A-7.

Referring now to FIGS. 2A, 2B, illustrated is a packaged multi-chip device 200. The packaged multi-chip device 200 may be substantially similar to the device 10, discussed above with reference to FIG. 1. A thermal management component 202 is disposed on and interfacing the packaged multi-chip device 200. The thermal management component 202 may be substantially similar to the thermal management component 12, discussed above with reference to FIG. 1.

The cross-sectional view of the packaged multi-chip device 200 illustrates three chips or die 204A, 204B, and 204C. However, any number of chips or die may be included in the packaged multi-chip device 200, including additional numbers of die 204A and 204C as shown in the top view of FIG. 2A. In an embodiment, the die 204A and/or 204C are a memory device such as a high-band width memory (HBM) die. In an embodiment, the device 204B is a logic device. Exemplary die may include a plurality of semiconductor devices such as, for example, diode based devices, resistive-capacitive based devices, transistor based devices, silicon-controller rectifiers, PNP transistors, NPN transistors, n-channel metal-oxide-semiconductor (NMOS) transistors, p-channel metal-oxide-semiconductor (PMOS) transistors, field oxide devices, gate triggered devices, base triggered devices, substrate triggered devices, zener diodes, metal oxide varistors, transient voltage suppression diodes, complementary metal oxide semiconductors (CMOSs), bipolar clamp diodes, and combinations thereof. To that effect, each of the first die 204A, the second die 204B, and the third die 204C may include a plurality of transistors, such as planar transistors, fin-type field effect transistors (FinFETs), gate-all-around (GAA) transistors, nanowire transistors, nanosheet transistors, or other multi-gate transistors.

The packaged multi-chip device 200 has a package substrate 206. The package substrate 206 may include a printed circuit board (PCB) or suitable substrate. In order to electrically contact devices in the packaged multi-chip device 200, connectors 207 such as controlled collapse chip connection (C4) bumps, solder bumps, or other features are provided on the package substrate 206.

The first die 204A, the second die 204B, and the third die 204C (and any additional die) are connected, physically and electrically, to an interposer substrate 208 by way of a plurality of micro-bumps or other interconnections. The space between each of the first die 204A, the second die 204B, and the third die 204C (and/or the space between the die and the interposer 208) and may be filled with an underfill 210. A molding compound 212 (also referred to as an encapsulation layer) may be provided surrounding the die to provide structural support and environmental protection. The molding compound 212 may include polymer, resin, epoxy, silicon oxide (silica), aluminum oxide, and/or other suitable materials. In an embodiment, the interposer 208 may include a semiconductor material such as a silicon (Si) substrate. In some alternative embodiments, the interposer 208 includes silicon germanium (SiGe), silicon carbon (SiC), glass and/or other suitable materials. The interposer 208 includes interconnect layers, such as redistribution layers, connected to each of the first die 204A, the second die 204B, and third die 204C. And through substrate vias (TSV) may carry the respective signals through the interposer 208 to connectors (e.g., microbumps, pillars, C4 bumps, and other suitable connections) between the interposer 208 and the package substrate 206. The connectors between the interposer 208 and the package substrate may be copper, solder or similar conductive materials. An underfill 210 may interpose the package substrate 206 and the interposer 208. The underfill 210 between the interposer substrate 208 and the package substrate 206 may be the same or different than the underfill 210 between die 204A, 204B, 204C. The underfill 210 may include polymer, epoxy, and/or other suitable materials.

In an embodiment, one or more of the dies 204A, 204B and 204C are oriented in a flip-chip orientation such that the device layers (e.g., transistors) are facing downwards and a backside of a device substrate is exposed on a top surface of the packaged multi-chip device 200. In an embodiment, the device substrate(s) are a silicon substrate. While the substrate may be a bulk silicon substrate in some embodiments, other semiconductor materials including group III, group IV, and group V elements may also be used. Alternatively, the substrate may be a silicon-on-insulator (SOI) substrate. Thus, in an embodiment, a silicon substrate surface is exposed at a top surface of the die 204A, 204B, and/or 204C. In some implementations, a dielectric or other protective layer is formed on the backside of the device substrate and is exposed on a top surface of the packaged multi-chip device 200. The exposed upper surface of the device 200 between die 204A, 204B, and 204C may include underfill 210.

Interfacing an upper surface of the packaged multi-chip device 200 is the thermal management component 202. The thermal management component 202 may be substantially similar to the thermal management component 12, discussed above with reference to FIG. 1. The thermal management component 202 includes a manifold 214 that provides an assembly for receiving plumbing for coolant inlet pipe(s) 218 to the thermal management component 202 and plumbing for coolant outlet pipes(s) 220 from the thermal management component 202. The coolant inlet pipes 218 and coolant outlet pipes 220 may be connected to a coolant handling system such as the coolant handling system 16 discussed above with reference to FIG. 1.

In the illustrated embodiment of the thermal management component 202, within the manifold 214, direct cooling compartments 216 (labeled 216A, 216B, 216C respectively in FIG. 2B) are located. The direct cooling compartments may be chambers within which a fluid (e.g., liquid) can be contained such as a fluid may be flowed from one side of the compartment to another side of the compartment. During the flow from one side of the compartment to another side of the compartment, the coolant flows over the upper surface of the device 100 that interfaces the compartment. A sealant 222 is provided along the periphery of the direct cooling compartments 216 and between the compartments 216 and an upper surface of the packaged multi-chip device 200. The sealant 222 may be an impermeable adhesive such as an epoxy, resin or other material. The sealant 222 may also include mechanical attachment means, gaskets, clamps or the like. In some implementations, the sealant 222 is suitable to provide a leak-tight connection between the packaged device (e.g., surface of the die 204A/B/C) and the direct cooling compartment 216. In an embodiment, a gap is disposed between the sealant 222, the manifold 214, and the packaged multi-chip device 200 between compartments 216A/216B/216C.

As illustrated in the embodiment of FIGS. 2A, 2B, a single direct cooling compartment 216A, 216B, or 216C is located over each of the dies 204A, 204B, and 204C, respectively. A first inlet pipe 218A having a first control valve 224A is configured to provide coolant to the first direct cooling compartment 216A that is located over the first die 204A. A second pipe 218B having a second control valve 224B is provided to provide coolant to the second direct cooling compartment 216B that is located over the second die 204A. A third pipe 218C having a third control valve 224C is provided to provide coolant to the third direct cooling compartment 216C that is located over the third die 204C. The coolant delivery to each of the direct cooling compartments may be separately controlled by a control system such as the control system 14 discussed above with reference to FIG. 1. In some implementations, in the direct cooling compartments 216A, 216B, 216C, coolant, delivered from the respective pipe 218A, 218B, 218C is directly provided onto an upper, exposed surface of the device 200 and in particular, the upper, exposed surface of respective dies 204A, 204B, 204C. That is, in an embodiment, the coolant is provided directly to a backside of a device substrate (e.g., silicon substrate) of the respective chip. In a further embodiment, the coolant provided may be a liquid coolant. Exemplary coolant compositions include de-ionized water, alcohol, polymer liquid, and/or other heat conducting liquids.

Outlet pipes remove the coolant (i.e., spent coolant) from the direct cooling compartments 216A, 216B, 216C. In an embodiment, the coolant is moved across the compartment by pump, pressure or other suitable mechanism. In some implementations, the coolant provided in the outlet pipes 220A, 220B, 220C (e.g., spent coolant) is in gaseous state. In other implementations, the coolant (e.g., spent coolant) is provided in a liquid state. The coolant of the outlet pipes 220A, 220B, 220C (e.g., spent coolant) is greater in temperature than that of the respective inlet pipes 218A, 218B, 218C due to the heat transfer from the respective dies 204A, 204B, 204C. To be sure, the configuration of the piping route of the inlet pipes 218 and the outlet pipes 220 are exemplary only and may be provided to the compartments using a different routing depending on the design shape and environmental factors such as adjacent temperature of adjacent pipes.

Because the coolant supply is separately controlled to each of the direct cooling compartments 216A, 216B, 216C, the thermal conditions to each of the die 204A, 204B and 204C may be separately controlled. For example, a first coolant of a first flow rate may be provided at the first inlet pipe 218A to the first direct cooling compartment 216A that is located over the first die 204A to provide a first level of cooling. A second coolant of a second flow rate may be provided at the second inlet pipe 218B to the second direct cooling compartment 216B that is located over the second die 204B to provide a second level of cooling. The second flow rate, coolant type, and/or level of cooling may be different than the first flow rate, coolant type and/or level of cooling. A third coolant of a third flow rate may be provided at the third pipe 218C to the third direct cooling compartment 216B that is located over the third die 204B to provide a third level of cooling. The third flow rate, coolant type, and/or level of cooling may be different than the first flow rate, coolant type and/or level of cooling and/or second flow rate, coolant type, and/or level of cooling. In an embodiment, the second die 204B is a die of a performance (e.g., high power) that generates additional heat that is addressed by additional cooling being provided by the second direct cooling compartment 216B. During operation of the device, such as in testing, the thermal conditions to each region of the thermal management component may be adjusted. In an embodiment, a diameter of a pipe to one compartment (e.g., 216 overlying logic device 204B) may be greater than other pipe diameters.

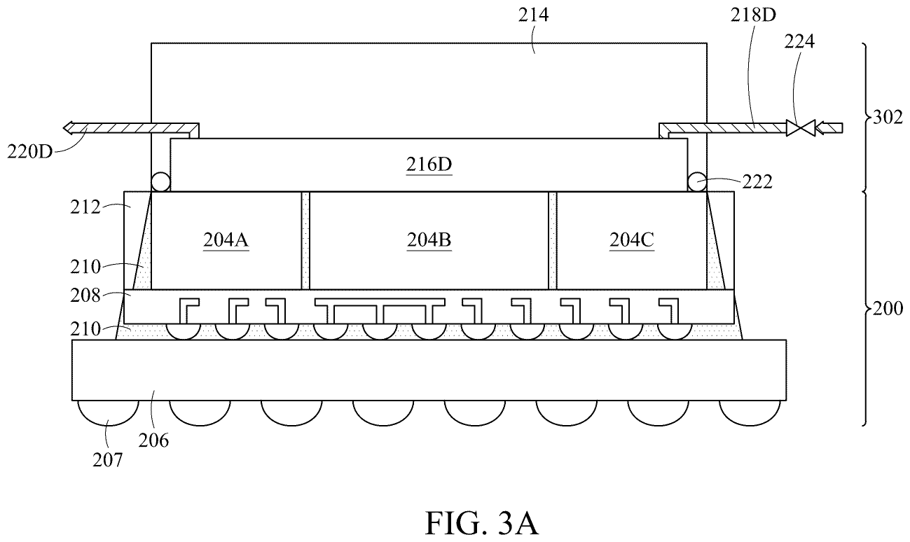

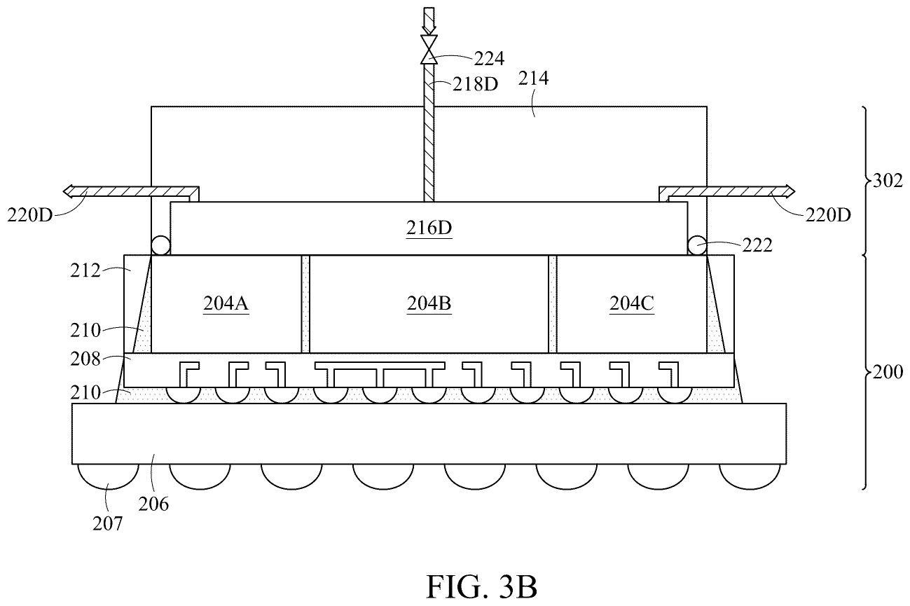

Referring now to FIGS. 3A and 3B, illustrated is the packaged multi-chip device 200, which may be substantially similar to as discussed above. A thermal management component 302 is disposed on and interfacing the packaged multi-chip device 200. The thermal management component 302 may be substantially similar to the thermal management component 12, discussed above with reference to FIG. 1 and share aspects with the thermal management component 202, discussed above with reference to FIGS. 2A, 2B, with differences noted. Similar reference numbers denote similarly configured features.

The thermal management component 302 includes a manifold 214 that provides an assembly for plumbing for a single coolant inlet pipe 218D and plumbing for a single coolant outlet pipe 220D. Within the manifold 214, a single direct cooling compartment 216D is located. The direct cooling compartment 216D is a compartment or chamber within which a fluid (e.g., liquid coolant) can be contained where the compartment extends over more than one die of the packaged multi-chip device 200 (e.g., over die 204A, 204B, and 204C). A sealant 222 is provided between the periphery of the direct cooling compartment 216D and an upper surface of the packaged multi-chip device 200. In some implementations, the sealant 222 is suitable to provide a leak-tight connection between the surface of the packaged multi-chip device 200 and the direct cooling compartment 216D. In an embodiment, the edge of the direct cooling compartment 216D is over a die of the packaged multi-chip device 200 for example, a first sealant location may be located on an upper surface of the die 204A and a second sealant location may be located on an upper surface of the die 204C.

As illustrated in FIGS. 3A, 3B, the single direct cooling compartment 216D is located over all of die 204A, 204B, and 204C. The coolant delivery to the direct cooling compartment 216D may be controlled by a control system such as the control system 14 discussed above with reference to FIG. 1. In some implementations, in the direct cooling compartment 216D, coolant, delivered from the inlet pipe 218D is directly provided to an upper surface of the dies 204A, 204B, 204C. In an embodiment, the coolant over the die 204C is a lower temperature than the die 204B, and the coolant over the die 204B is a lower temperature than the coolant over the die 204A. Thus, the thermal management component 302 may provide for enhanced cooling of the die 204C versus that of die 204B and 204A. As discussed above, an outlet pipe 220D removes the coolant (i.e., spent coolant at an increased temperature) from the direct cooling compartment 216D. The entry point of the inlet pipe 218D may vary as illustrated by a comparison of FIGS. 3A, 3B.

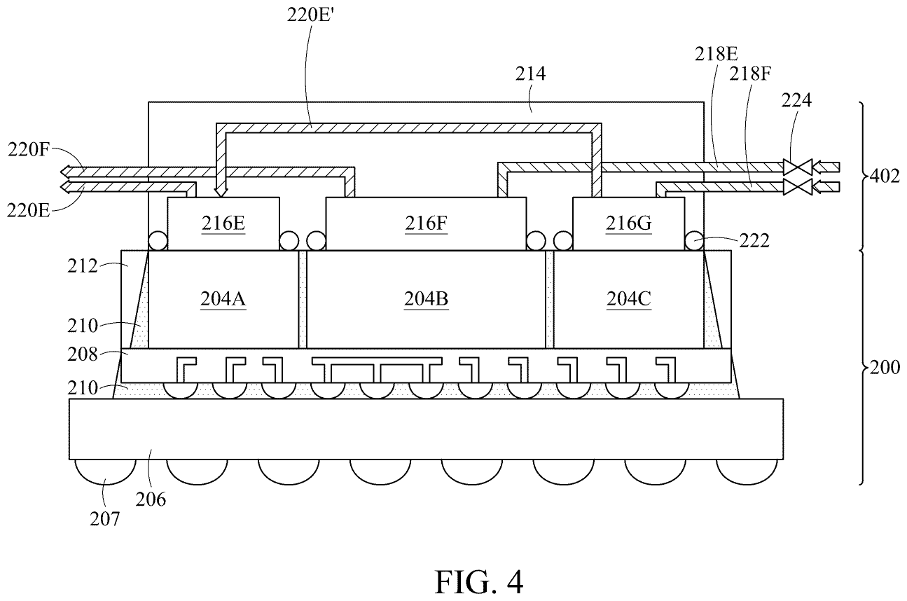

Referring now to FIGS. 4A, 4B, illustrated is the packaged multi-chip device 200, which may be substantially similar to as discussed above. A thermal management component 402 is disposed on and interfacing the packaged multi-chip device 200. The thermal management component 402 may be substantially similar to the thermal management component 12, discussed above with reference to FIG. 1 and share aspects with the thermal management component 202, discussed above with reference to FIG. 2, with differences noted. Similar reference numbers denote similarly configured features.

The thermal management component 402 includes a manifold 214 that provides an assembly for plumbing for two coolant inlet pipes 218E, 218F and plumbing for two coolant outlet pipes 220E, 220F. Within the manifold 214, three direct cooling compartments 216E, 216F, 216G are located. The direct cooling compartments 216E, 216F, and 216G may be substantially similar to the direct cooling compartments 216A, 216B, and 216C respectively, described above with reference to FIG. 2. The direct cooling compartments 216E, 216F, 216G each provide a chamber within which a fluid (e.g., liquid coolant) can be contained that extends over one of the dies of the packaged multi-chip device 200 (e.g., over one of die 204A, 204B, or 204C, respectively).

As illustrated in FIG. 4, a first inlet coolant pipe 218E is connected to the direct cooling compartment 216F to provide a coolant and a second inlet coolant pipe 218F is connected to the direct cooling compartment 216G to provide a coolant. The coolant delivery to the direct cooling compartment 216G and direct cooling compartment 216F may be controlled by a control system such as the control system 14 discussed above with reference to FIG. 1. In the implementation of the embodiment of FIG. 4, an outlet coolant pipe 220E′extends from direct cooling compartment 216G to a direct cooling compartment 216E. That is, in an embodiment, the coolant having received some heat transfer within the compartment 216G from the die 204C, is then provided to the compartment 216E for thermal treatment (e.g., cooling) of the die 204A. The coolant is a first temperature at the inlet of the direct cooling compartment 216G, a second temperature, greater than the first, at the outlet of the direct cooling compartment 216G, and a third temperature, greater than the second temperature at the outlet 220E of the direct cooling compartment 216E. In an embodiment, the die 204C and 204A are memory devices. In the embodiment illustrated, an inlet coolant pipe 218E is provided to the direct cooling compartment 216F and an outlet coolant pipe 220F is provided from the direct cooling compartment 216F. Thus, the thermal conditions of one die, 204B, may be separately controlled from the thermal conditions of other die (e.g., 204A and 204C) of the system, while the die 204A and 204C are controlled together.

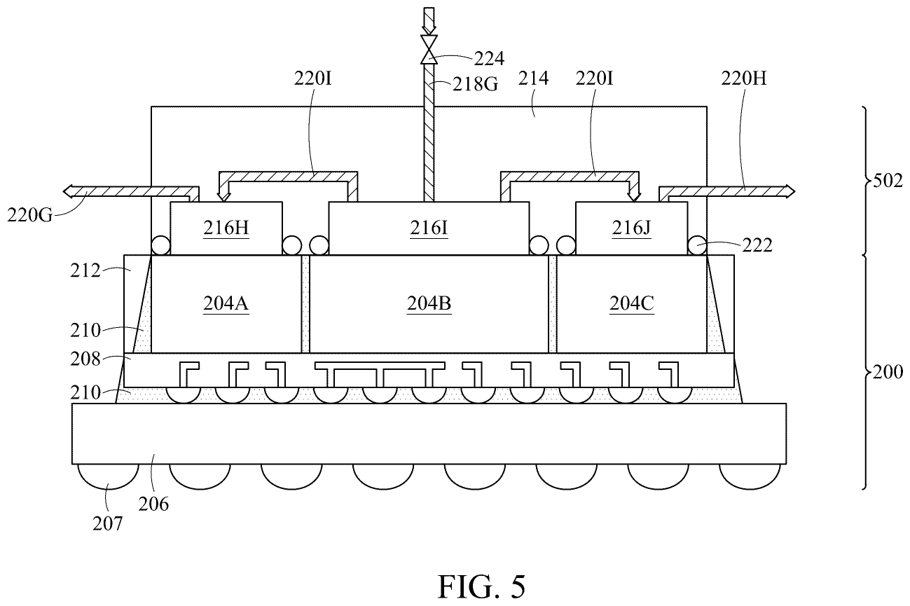

Referring now to FIG. 5A, illustrated is the packaged multi-chip device 200, which may be substantially similar to as discussed above. A thermal management component 502 is disposed on and interfacing the packaged multi-chip device 200. The thermal management component 502 may be substantially similar to the thermal management component 12, discussed above with reference to FIG. 1 and share aspects with the thermal management component 202, discussed above with reference to FIGS. 2A-4, with differences noted. Similar reference numbers denote similarly configured features.

The thermal management component 502 includes a manifold 214 that provides an assembly for plumbing for one coolant inlet pipe 218G and plumbing for two coolant outlet pipes 220G, 220H. Within the manifold 214, three direct cooling compartments 216H, 216I, 216J are located. The direct cooling compartments 216H, 216I, and 216J may be substantially similar to the direct cooling compartments 216A, 216B, and 216C respectively, described above with reference to FIGS. 2A, 2B. The direct cooling compartments 216H, 216I, 216J each provide a compartment or chamber within which a fluid can be contained such that the coolant can extend over the portion of the device 200 exposed in the compartment (e.g., one or more of the dies of the packaged multi-chip device 200 (e.g., over one of die 204A, 204B, or respectively)).

As illustrated in FIG. 5, a first inlet coolant pipe 218G is connected to the direct cooling compartment 216I to provide a coolant. The coolant delivery to the direct cooling compartment 216I may be controlled by a control system such as the control system 14 discussed above with reference to FIG. 1. In the implementation of the embodiment of FIG. 5, an outlet coolant pipe 2201 extends from direct cooling compartment 216I to a direct cooling compartment 216H, and an outlet coolant pipe 2201 extends from direct cooling compartment 216I to direct cooling compartment 216J. Outlet coolant pipes 220G and 220H extend from the direct cooling compartments 216H and 216J respectively.

In other embodiments, the number of inlet piping is greater than a quantity of outlet piping such as when thermal coolant from one compartment is delivered to another compartment without an outlet pipe extending out of the thermal management component itself. In other embodiments, the quantity of inlet pipes may be less than the quantity of outlet pipes.

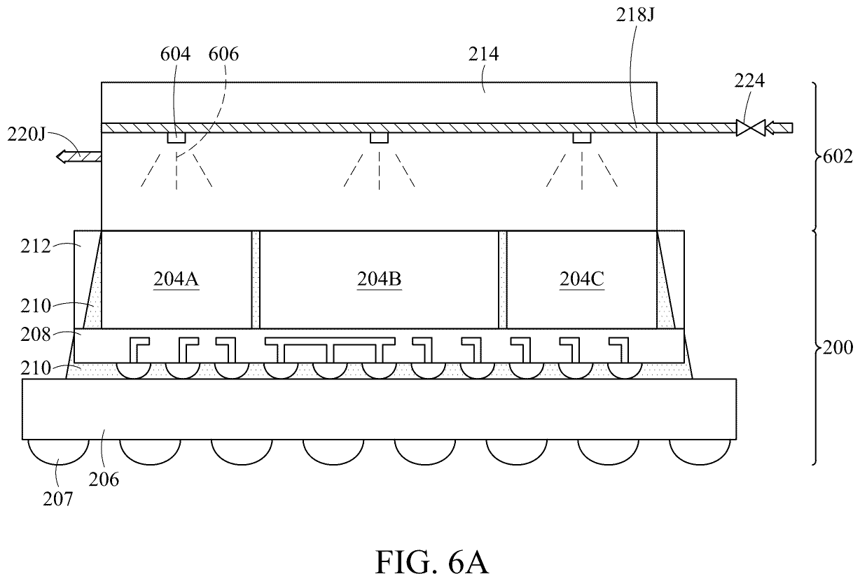

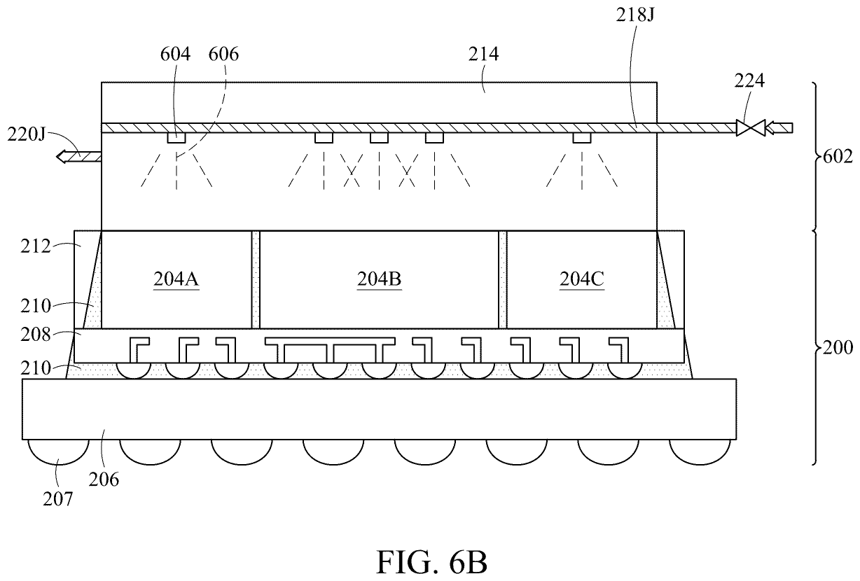

Referring now to FIGS. 6A, 6B, illustrated is the packaged multi-chip device 200, which may be substantially similar to as discussed above. A thermal management component 602 is disposed on and interfacing the packaged multi-chip device 200. The thermal management component 602 may be substantially similar to the thermal management component 12, discussed above with reference to FIG. 1 and share aspects with the thermal management component 202, discussed above with reference to FIG. 2B, with differences noted. Similar reference numbers denote similarly configured features.

The thermal management component 602 includes a manifold 214 that provides an assembly for plumbing for a coolant inlet pipe 218J and plumbing for a coolant outlet pipe 220J. Similar to the embodiments above, a valve 224 is provided to control the coolant provided by coolant inlet pipe 218J such as by a control system such as control system 14 of FIG. 1. Within the manifold 214, three different zones or regions are provided, each zone corresponding to a die 204A, 204B, or 204C respectively. A spray head is 604 is provided in each zone. The spray head 604 may be operable to deliver a coolant 606 to an upper surface of the packaged multi-chip device 200. In an embodiment, the coolant 606 is delivered to a top surface of each die 204A, 204B and 204C (e.g., to an exposed portion of the device substrate of each die). The coolant 606 may be delivered in liquid-phase. While independent control of the cooling of each zone may not be provided in the embodiment, cooling efficiency may be increased. FIG. 6B illustrates that the spray head 604 over one chip, e.g., 204B, may provide a greater amount of coolant 606. To be sure, each spray head 604 may include more than one nozzle delivering coolant including in FIG. 6A. FIG. 6B's illustration being suggestive only of the number of nozzles/spray heads delivering coolant being greater over one die than another.

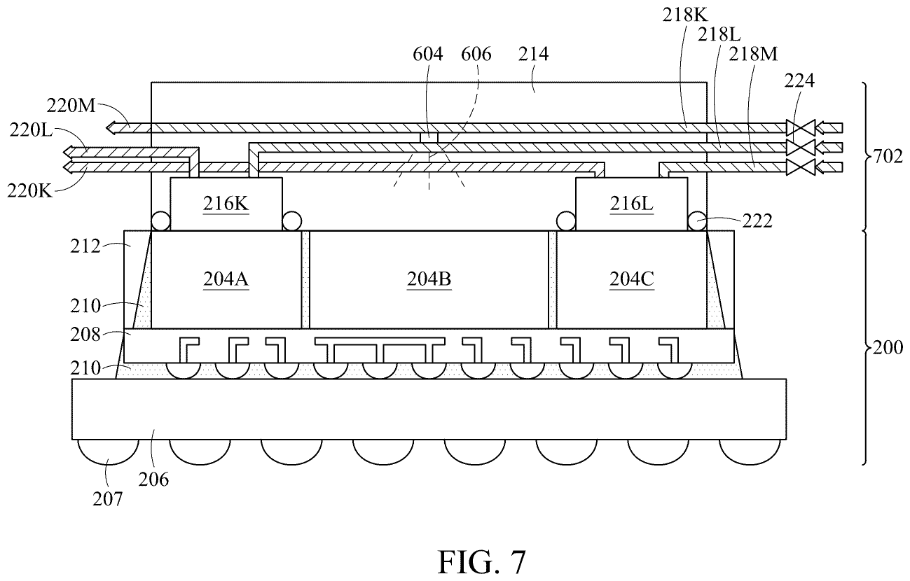

Referring now to FIG. 7, illustrated is the packaged multi-chip device 200, which may be substantially similar to as discussed above. A thermal management component 702 is disposed on and interfacing the packaged multi-chip device 200. The thermal management component 702 may be substantially similar to the thermal management component 12, discussed above with reference to FIG. 1 and share aspects with the thermal management component 202, discussed with reference to FIG. 2B and the thermal management component 602, discussed with reference to FIG. 6. Similar reference numbers denote similarly configured features. As illustrated, die 204B experiences a thermal condition defined by a coolant 606 (e.g., liquid coolant) delivered from a spray head 604 disposed in the manifold 214 over the die 204B. And the die 204A and 204C experience thermal conditions defined by coolant (e.g., liquid coolant) being delivered to a direct cooling compartment 216K and 216L, respectively. Inlet pipes 218L, 218K, and 218M deliver coolant via controlled valves 224 to the respective direct cooling compartment or spray head; outlet pipes 220K, 220L, and 220M remove the coolant from the manifold 214.

The embodiment of FIG. 7 may provide for enhanced cooling efficiency in a desired region (e.g., die 204B). The embodiment of FIG. 7 also provides for control of each region of the thermal management component 702, and thus each die 204A, 204B, and 204C, separately. The embodiment of FIG. 7 may also be applied when testing conditions for each device vary during a single test, e.g., one die is desired to be kept at a lower target temperature than other die during a single test.

Referring now to FIG. 8, illustrated is a method 800 of testing a packaged semiconductor device and in particular useful for testing a multi-chip packaged semiconductor device. The method 800 may be implemented using the thermal management system 11, described above with reference to FIG. 1. The method 800 may also be implemented using aspects of one or more of the embodiments of FIGS. 2-7, discussed above. FIG. 8 has been simplified for the sake of clarity to better understand the inventive concepts of the present disclosure. Additional steps can be added in the method 800 and some of the steps described below can be replaced, modified, or eliminated in other embodiments of the testing method.

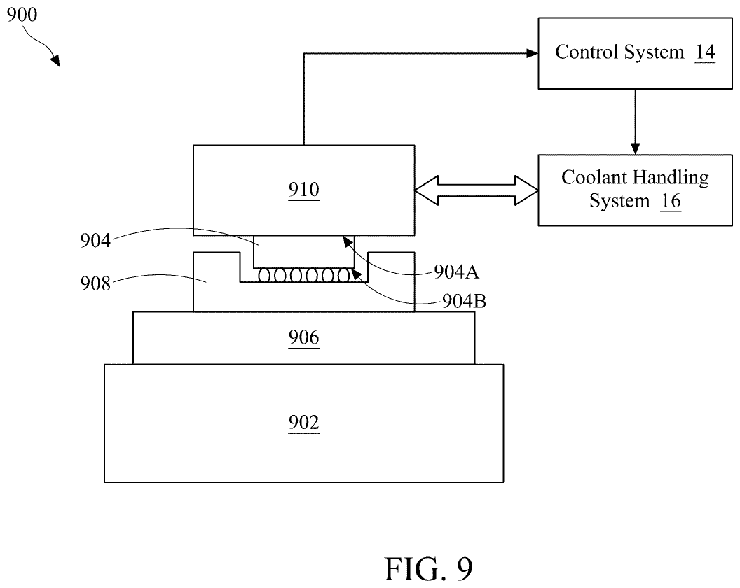

In block 802, a pick and place (PnP) arm places a device under test (DUT) in a test socket of a tester. In an embodiment, the device may be substantially similar to the packaged multi-chip device 200, discussed above including with reference to FIG. 2. The tester may be substantially similar to as discussed below with reference to FIG. 9. In block 804, a thermal test head may engage the DUT. In an embodiment, the thermal test head includes one or more of the thermal management components 12, 202, 302, 402, 502, 602 or 702 discussed above with reference to FIGS. 1, 2, 3, 4, 5, 6, and 7. The thermal test head may be selected based on the design of the DUT. For example, in an embodiment, the test head may be selected to provide a same number of thermal zones (e.g., separately controllable zones or regions) as die in the DUT (e.g., die exposed at a top surface of the DUT). The engagement of the test head and the DUT may be sufficient such that any sealing (see, e.g., sealant 222 discussed above) is sufficient to avoid leaking.

In block 806, a coolant is established to the test head and the thermal management component of the test head in particular. The coolant may be provided through piping as discussed above. In an embodiment, the coolant is determined using a control system such as the control system 14, which may provide instructions to valves of the cooling handling system, which is coolant handing system 16. The coolant may be a liquid coolant.

The method 800 then continues to block 808 where the testing of the DUT is performed. (In some implementations, the testing of block 808 may be initiated prior to the providing of the coolant in block 806.) The testing of the DUT may cause the DUT to generate heat. During the testing of the DUT at block 808 and the resultant generation of heat, the feedback of the DUT state (block 808A), such as feedback of a temperature of each zone of a multi-zoned thermal test head (e.g., thermal management component) may be provided to a control system. The feedback may be provided by a temperature sensor, voltage or power reading, and/or other suitable feedback mechanisms. The feedback may be provided to a control system such as the control system 14 discussed above in FIG. 1. During the testing, the thermal conditions provided by thermal test head and its thermal management component may be adjusted in block 808B based on the feedback of the thermal condition provided in block 808A. In an embodiment, adjusting the thermal conditions includes adjusting the coolant provided to one or more zones of the thermal management component of the test head, such as increasing a flowrate of coolant to a first region of the thermal management component of the test head through manipulation of valves in the inlet pipes to the thermal management component. The adjustment may be separately performed for each zone of the thermal management component, for example, a first coolant rate being increased to a first zone and a second coolant rate being decreased to a second zone. In an embodiment, the feedback of block 808A is compared to a desired testing temperature to determine the adjustment of block 808B. This feedback and adjustment to control the thermal conditions of one or more regions of the test head and thus the DUT may continue throughout the testing. It is noted that in some implementations, different tests may be performed that have different thermal setpoints. Thus, the adjustment of the thermal condition in block 808B may be based on a desired test condition.

In block 810, the testing of the DUT is terminated. Based on the test results of block 808, the DUTs may be classified and/or sorted also referred to as binning. The testing can evaluate DUTs' electrical characteristics, reliability, behavior, other characteristics and/or behaviors, or combinations thereof in response to various input and/or conditions (e.g., particular temperatures). Upon termination of the testing, the coolant delivery may be stopped. In an embodiment, a vacuum operation removes residual liquid coolant from a top surface of the DUT. The method 800 continues to block 812 where the thermal test head is disengaged, and block 814 where the PnP arm removes the DUT from the test socket.

Referring now to FIG. 9, illustrated is a block diagram of an exemplary test system 900 for IC testing, in portion or entirety, according to various aspects of the present disclosure. FIG. 9 has have been simplified for the sake of clarity to better understand the inventive concepts of the present disclosure. Additional features can be added in test system 900 and/or components thereof, and some of the features described below can be replaced, modified, or eliminated in other embodiments of test system 900 and/or components thereof. The test system 900 may perform the method 800, discussed above with reference to FIG. 8.

Test system 900 includes a tester 902 (also referred to as automatic/automated test equipment (ATE)). Test system 900 is configured to test a quality and/or a functionality of a device under test (DUT), such as a DUT 904. In an embodiment, the DUT 904 is a multi-die packaged IC such as discussed above. A test handler (such as a pick and place (PnP) component, not shown) may place the DUT 904 in mechanical and/or electrical contact with tester 902 via test interface 906, such as a load board or socket. The tester 902 performs tests on the DUTs 904 and evaluates performance and/or characteristics thereof. Based on the test results, the DUTs 904 are classified and/or sorted also referred to as binned by a test handler (not shown). Test system 902 can evaluate DUTs' electrical characteristics, reliability, behavior, other characteristics and/or behaviors, or combinations thereof in response to various input and/or conditions (e.g., particular temperatures). In some embodiments, test system 902 evaluates electrical characteristics and/or operation of DUTs at high temperatures. In some embodiments, test system 902 subjects DUTs to reliability tests, such as thermal cycling tests and/or thermal shock tests. These tests may be performed at a desired thermal condition (e.g., temperature) by controlling the thermal conditions through the thermal management component 910, discussed below.

DUT 904 has a surface 904A and a surface 904B, which may be referred to as a top surface and a bottom surface, respectively. DUT contacts are formed on surface 904B of an electrically conductive material. DUT contacts can be arranged on surface 904B to form a contact array/pattern, such as a ball grid array. In some embodiments, DUT contacts are solder balls such as illustrated above with reference to connectors 207, described with reference to FIG. 2. These contacts interface with the tester. In particular, a test interface 906 provides a mechanical and electrical interface between tester 902 and DUT 904, and test interface 906 routes signals between tester 902 and DUT 904, such as test signals from tester 902 to DUT 904 and response signals from DUT 904 to tester 902. Test interface 906 can include a load board, such as a printed circuit board (PCB), a socket mounted on load board, a test head or portion thereof, and/or other configurations. Configurations of test interface 906 depend on a type and/or a configuration of DUTs 904 being tested and are not limited by the present disclosure. An exemplary socket 908 is illustrated, which includes a cavity for receiving the DUT 904. In some implementations, the socket 908 also includes contacts, such as a probe card having probe pins, spring-loaded pins (e.g., pogo pins), various-shaped contacts disposed in elastomer, particle interconnects, other suitable types of contacts and/or interconnects, or combinations thereof.

A thermal management component 910, which may also provide a test head, is provided interfacing the surface 904A of the device 904. The thermal management component 910 may be substantially similar to the thermal management component 12, 203, 302, 402, 502, 602, and/or 702, discussed above with reference to FIGS. 2-7. The thermal management component 910 is coupled to the control system 14, which may be substantially similar to as discussed above with reference to FIG. 1. The thermal management component 910 may also be coupled to the coolant handling system 16, as also discussed above. In particular, the thermal management component 910 may be coupled to the coolant handling system 16 by inlet and outlet coolant piping. The thermal management component 910 may include one or more zones or regions that can be controlled to provide a thermal condition suitable for the DUT 904 during testing by the tester 902.

In one of the embodiments discussed herein a semiconductor device test system includes a packaged multi-die semiconductor device having a surface, a tester having a socket, the packaged multi-die semiconductor device disposed in the socket and a thermal management component. The thermal management component engages the packaged multi-die semiconductor device in the socket. And the surface of the packaged multi-die semiconductor device interfaces with the thermal management component. A coolant handling system operable to provide a coolant to the thermal management component is provided. A control system operable to control a supply of coolant from the coolant handing system to the thermal management component.

In a further embodiment, the coolant handling system includes a plurality of pipes extending to the thermal management component. In an embodiment, the thermal management component includes a sealed compartment interfacing the surface of the packaged multi-die semiconductor device. In some implementations, the thermal management component includes a first compartment and a second compartment, wherein a pipe extends from the first compartment to the second compartment. In an embodiment, in a top view, a sealed compartment of the thermal management component is centered on and comprised within a boundary defined by a die of the packaged multi-die component. In an embodiment, the thermal management component includes a plurality of sealed compartments for receiving coolant. In some implementations, the plurality of sealed compartments each interface the upper surface of the packaged multi-die semiconductor device. Exemplary confirmations provide a thermal management component having at least one spray nozzle.

In another of the broader embodiments, a method of testing a semiconductor device is provided. The method includes placing a packaged semiconductor device on a tester and engaging a thermal management component with an upper surface of the packaged semiconductor device. The packaged semiconductor device is tested using the tester, and during the testing a first thermal condition is delivered to a first region of the thermal management component while delivering a second thermal condition is delivered to a second region of the thermal management component. The first thermal condition is different than the second thermal condition.

In an embodiment, the thermal condition is delivered by supplying a first liquid coolant to the first region of the thermal management component and the second thermal condition is delivered by supplying a second liquid coolant to the second region of the thermal management component. In a further example, the first liquid coolant is delivered by a spray nozzle and the second liquid coolant is delivered to a sealed compartment interfacing a portion of the packaged semiconductor device. In an embodiment, the first region is a sealed compartment interfacing a first region of the upper surface of the packaged semiconductor device and the second region is another sealed compartment interfacing a second region of the upper surface of the packaged semiconductor device. In an embodiment, the first region of the upper surface of the packaged semiconductor device is a first die and the second region of the upper surface of the packaged semiconductor device is a second die.

In some implementations, the method includes determining a first temperature associated with the first region and determining a second temperature associated with the second region. The second temperature is different than the first temperature. In an embodiment, the method also includes setting a first target temperature for the first region, and setting a second target temperature for the second region.

In another of the broader embodiments, a method of adjusting a thermal environment of a semiconductor structure is provided. The method includes providing a multi-die packaged semiconductor device and providing a thermal management component interfacing an upper surface of the multi-die packaged semiconductor device. In an embodiment, during an operation of the multi-die packaged semiconductor device, the method includes delivering a first liquid coolant to a first region of the thermal management component. The first region overlies a first die of the multi-die packaged semiconductor device. The method also includes delivering a second liquid coolant to a second region of the thermal management component. The second region overlies a second die of the multi-die packaged semiconductor device, and delivering the second liquid coolant is concurrent with the delivering the first liquid coolant.

In an embodiment, the first region of the thermal management component is a first sealed compartment. A side of the first sealed compartment is defined by an upper surface of the first die. The second region of the thermal management component includes a spray delivery disposed over an upper surface of the second die. In an embodiment, the second region of the thermal management component includes a second sealed compartment and a side of the second sealed compartment is defined by an upper surface of the second die. In some implementations, the method includes delivering a third liquid coolant to a third region of the thermal management component and the third region overlies a third die of the multi-die packaged semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device test system, comprising:
a packaged multi-die semiconductor device having a surface;
a tester having a socket, the packaged multi-die semiconductor device disposed in the socket;
a thermal management component engaging the packaged multi-die semiconductor device in the socket, wherein the surface of the packaged multi-die semiconductor device interfaces with the thermal management component;
a coolant handling system operable to provide a coolant to the thermal management component; and
a control system operable to control a supply of coolant from the coolant handing system to the thermal management component.

2. The system of claim 1, wherein the coolant handling system includes a plurality of pipes extending to the thermal management component.

3. The system of claim 1, wherein the thermal management component includes a sealed compartment interfacing the surface of the packaged multi-die semiconductor device.

4. The system of claim 1, wherein the thermal management component includes a first compartment and a second compartment, wherein a pipe extends from the first compartment to the second compartment.

5. The system of claim 1, wherein in a top view, a sealed compartment of the thermal management component is centered on and comprised within a boundary defined by a die of the packaged multi-die semiconductor device.

6. The system of claim 1, wherein the thermal management component includes a plurality of sealed compartments for receiving coolant.

7. The system of claim 6, wherein the plurality of sealed compartments each interface the surface of the packaged multi-die semiconductor device.

8. The system of claim 1, wherein the thermal management component includes at least one spray delivery.

9. A method of testing a semiconductor device, the method comprising:
placing a packaged semiconductor device on a tester;
engaging a thermal management component with an upper surface of the packaged semiconductor device; and
testing the packaged semiconductor device using the tester, and during the testing delivering a first thermal condition to a first region of the thermal management component while delivering a second thermal condition to a second region of the thermal management component, wherein the first thermal condition is different than the second thermal condition.

10. The method of claim 9, wherein the first thermal condition is delivered by supplying a first liquid coolant to the first region of the thermal management component and the second thermal condition is delivered by supplying a second liquid coolant to the second region of the thermal management component.

11. The method of claim 10, wherein the first liquid coolant is delivered by a spray and the second liquid coolant is delivered to a sealed compartment interfacing a portion of the packaged semiconductor device.

12. The method of claim 9, wherein the first region is a sealed compartment interfacing a first region of the upper surface of the packaged semiconductor device and wherein the second region is another sealed compartment interfacing a second region of the upper surface of the packaged semiconductor device.

13. The method of claim 12, wherein the first region of the upper surface of the packaged semiconductor device is a first die and the second region of the upper surface of the packaged semiconductor device is a second die.

14. The method of claim 9, further comprising:
determining a first temperature associated with the first region and determining a second temperature associated with the second region, wherein the second temperature is different than the first temperature.

15. The method of claim 9, further comprising:
setting a first target temperature for the first region, and
setting a second target temperature for the second region.

16. A method of adjusting a thermal environment of a semiconductor structure, the method comprising:
providing a multi-die packaged semiconductor device;
providing a thermal management component interfacing an upper surface of the multi-die packaged semiconductor device;
during an operation of the multi-die packaged semiconductor device, delivering a first liquid coolant to a first region of the thermal management component, wherein the first region overlies a first die of the multi-die packaged semiconductor device; and
delivering a second liquid coolant to a second region of the thermal management component, wherein the second region overlies a second die of the multi-die packaged semiconductor device, and wherein the delivering the second liquid coolant is concurrent with the delivering the first liquid coolant.

17. The method of claim 16, wherein the first region of the thermal management component is a first sealed compartment, wherein a side of the first sealed compartment is defined by an upper surface of the first die.

18. The method of claim 17, wherein the second region of the thermal management component includes a spray nozzle disposed over an upper surface of the second die.

19. The method of claim 17, wherein the second region of the thermal management component includes a second sealed compartment, wherein a side of the second sealed compartment is defined by an upper surface of the second die.

20. The method of claim 16, further comprising:
delivering a third liquid coolant to a third region of the thermal management component, wherein the third region overlies a third die of the multi-die packaged semiconductor device.
